(19) United States
(12) Patent Application Publication
(10) Pub. No.: US 2026/0090316 A1
(43) Pub. Date: Mar. 26, 2026

(54) APPARATUS AND METHOD FOR TREATING WAFERS USING GUIDING ELEMENTS

(71) Applicant: SINGULUS TECHNOLOGIES AG, Kahl am Main (DE)

(72) Inventors: Martin Maximilian MENSCHICK, München (DE); Mirza CORDA, Maisach (DE)

(21) Appl. No.: 19/404,282

(22) Filed: Dec. 1, 2025

Related U.S. Application Data
(63) Continuation of application No. PCT/EP2024/064474, filed on May 27, 2024.

(30) Foreign Application Priority Data
May 31, 2023 (DE) 10 2023 205 059.5

(51) Int. Cl. H10P 72/00

(52) U.S. Cl. CPC H10P 72/0426

(57) ABSTRACT

An apparatus for treating wafers includes a basin, a hole plate, a filling pipe and guiding elements. The basin serves to receive a treatment liquid and the wafers to be treated. The hole plate separates the basin in an upper and lower areas, wherein the hole plate comprises holes that fluidically connect the lower area and the upper area. The upper area comprises a receiving area for one or several wafer carriers in which wafers are arranged side-by-side with a gap in between. The filling pipe is disposed in the lower area of the basin and comprises filling pipe openings along its longitudinal direction. The guide elements are disposed in the upper area of the basin, in addition to the outer walls of the basin, and laterally limit the receiving area of at least one wafer carrier to concentrate a flow of the treatment liquid on the receiving area.

### CROSS-REFERENCE TO RELATED APPLICATIONS

This application is a continuation of International Application No. PCT/EP2024/064474, filed May 27, 2024, which is incorporated herein by reference in its entirety, and additionally claims priority from German Application No. 10 2023 205 059.5, filed May 31, 2023, which is also incorporated herein by reference in its entirety.

The present invention relates to apparatuses and methods for treating wafers and in particular to apparatuses and methods for treating wafers in batch operation, wherein a plurality of wafers in a wafer carrier, for example, a wafer carrier usually referred to as basket or carrier, is placed in a basin and treated with a treatment liquid.

### BACKGROUND OF THE INVENTION

Different methods for treating wafers with liquids are known from conventional technology. EP 0 762 482 B1 describes apparatuses and methods for etching wafers, wherein a wafer carrier is disposed in a basin. In the basin, a lateral wall having holes through which the treatment liquid is supplied from a side of the etching basin is arranged. The treatment liquid flows through the etching basin such that, in the vicinity of the surface of the liquid, a horizontal laminar surface flow is formed and, in the vicinity of the semiconductor wafers, a rotating flow essentially concentric to the respective wafer center is effected.

From TW 202003124 A, an apparatus for cleaning wafers in a batch method is described, wherein a wafer carrier is introduced into a basin. A hole plate having a plurality of equally disposed openings is provided In a lower area of the basin. Below the hole plate, pipes are provided that comprise openings directed towards a bottom wall of the basin, such that liquid can be directed, by means of a pump, through the openings of the pipes and from there through the hole plate and past the wafers for cleaning the wafers. It is described that, during rinsing, first, the wafers are rinsed from bottom to top and subsequently rinsed from top to bottom.

In known methods, there is a problem that uniform treatment of the wafers is difficult to obtain during treatment in the batch method. Here, the treatment intensity, for example, the etching rate, can depend on the flow through circulation of the treatment medium, from a different homogeneity of the treating medium across a base area of the bath, within the wafer carrier or between different wafer carriers within one bath. In particular for a larger number of wafer carriers within one batch process, for example, six wafer carriers or eight wafer carriers, the arrangement of the wafer carriers can be asymmetrical, such that the flow runs off at the bath surface towards the sidewall of the basin, where a lateral overflow can occur.

For solving these problems, for example, flow control via the configuration of a hole plate below or on the sides of the wafer carriers is possible, wherein reference can be made to the above-stated references. Inlet pipes below the wafer carriers could be configured to locally change the flow. Further, diffuse media distribution via gas bubbles could be used in addition to circulation.

### SUMMARY

According to an embodiment, an apparatus for treating wafers with a treatment liquid may have: a basin for receiving the treatment liquid and the wafers to be treated; a hole plate separating the basin in an upper area and a lower area, wherein the hole plate includes holes that fluidically connect the lower area and the upper area, wherein the upper area includes a receiving area for one or several wafer carriers in which wafers are each disposed side-by-side with a gap in between; and a filling pipe disposed in the lower area of the basin and including filling pipe openings along its longitudinal direction; characterized by guiding elements that are disposed in the upper area of the basin, in addition to outer walls of the basin, and laterally limit the receiving area of at least one wafer carrier to concentrate a flow of the treatment liquid on the receiving area, wherein the guiding elements extend from the hole plate to a height corresponding at least to the height of the at least one wafer carrier.

According to another embodiment, a method for treating wafers with a treatment liquid using an inventive apparatus may have the steps of: introducing at least one wafer carrier into the upper area of the basin by using the guiding elements as guide; and pumping the treatment liquid by means of the pump into the filling pipe and through the filling pipe openings to thereby bring liquid through the holes in the hole plate into the upper area of the basin to treat wafers in the wafer carrier with the treatment liquid.

Examples of the invention provide an apparatus for treating wafers with a treatment liquid, comprising:
a basin for receiving the treatment liquid and the wafers to be treated;
a hole plate separating the basin in an upper area and a lower area, wherein the hole plate comprises holes that fluidically connect the lower area and the upper area, wherein the upper area comprises a receiving area for one or several wafer carriers in which wafers are each disposed side-by-side with a gap in between; and
a filling pipe disposed in the lower area of the basin and comprising filling pipe openings along its longitudinal direction,
characterized by guiding elements that are disposed in the upper area of the basin, in addition to outer walls of the basin, and laterally limit the receiving area of at least one wafer carrier to concentrate a flow of the treatment liquid on the receiving area.

Examples of the invention are based on the finding that it is possible, by providing respective guiding elements, to concentrate a flow of the treatment liquid on the receiving area and hence through wafer carriers to be disposed in the same. Here, lateral means laterally with respect to the longitudinal direction of the filling pipe. The guiding elements can represent elements beside the wafer carriers, that separate the wafer carriers, that force the flow through the wafer carriers and hence, to the surfaces of the wafers, i.e., the wafer sides and prevent lateral evasion of the flow. In that way, the guiding elements allow a specific guidance of the treatment liquid through the wafer carriers and hence, also a homogenous flow through the same. Thus, the guiding elements can further improve the homogenization of the treatment with a treatment liquid. The guiding elements can be configured to be disposed above holes of areas of the hole plate above which no receiving area for wafer carriers is disposed. The guiding elements are part of the apparatus for treating wafers and are not part of the wafer carrier(s). Thus, the guiding elements are not moved with the wafer carrier(s) and are fixed in the apparatus for treating wafers.

In examples, the guiding elements limit the receiving area of the at least one wafer carrier on two sides that extend in parallel to the longitudinal extension of the filling pipe. Normally, the dimension of the wafer carriers in the longitudinal direction of the filling pipe is greater than in the direction perpendicular thereto, i.e., the transversal direction. Thus, respective examples allow the flow to be accordingly concentrated on the receiving area across both longer sides of the wafer carrier.

In examples, the guiding elements are further configured to position the at least one wafer carrier in the basin. Thus, examples allow an exact positioning of the wafer carrier(s) in the basin at a defined position above the hole plate.

In examples, the gap between the guiding elements transversal to the longitudinal direction of the filling pipe can correspond to a dimension of the wafer carrier transversal to the longitudinal direction of the filling pipe. Thereby, examples allow an exact positioning of the wafer carrier(s) and further prevent liquid from flowing laterally past the wafer carriers.

In examples, the guiding elements are configured to allow positioning of wafer carriers comprising spaced-apart end plates in the longitudinal direction of the filling pipe. In such examples, a length of the guiding elements in the longitudinal direction of the filling pipe can correspond to a gap between these end plates of the wafer carrier. Thus, such examples also allow exact positioning of the wafer carrier(s) in the longitudinal direction of the filling pipe.

In examples, a plurality of respective guiding elements can be provided that laterally limit the receiving areas for a plurality of wafer carriers, such that a plurality of wafer carriers, for example four, six or more wafer carriers can be placed in the upper area of the basin at defined positions. Here, at least one of the guiding elements can be configured to be disposed between two adjacent receiving areas and to limit the sides of the two adjacent receiving areas that are facing each other.

In examples, the guiding elements extend from the hole plate to a height corresponding at least to the height of the at least one wafer carrier. In other words, at least some of the guiding elements extend across the entire height of the receiving area or several receiving areas in order to concentrate the flow across the entire height through the wafer carriers.

In examples, the holes in the hole plate are distributed at least across the receiving area(s) in order to allow a uniform flow through the wafer carriers in the receiving area(s).

In examples, the apparatus further comprises a pump for pumping the treatment liquid into the filling pipe and through the filling pipe openings. In examples, the filling pipe openings are directed towards a bottom of the basin. In examples, the treatment liquid is pumped through the filling pipe openings in the direction of the bottom of the basin. By pumping the liquid in the direction of the bottom of the basin, the liquid is distributed in transversal direction in the lower area of the basin and can reach the upper area of the basin through the hole plate.

Examples provide a method for treating wafers with a treatment liquid using one of the apparatuses as described herein. Here, at least one wafer carrier is introduced into the upper area of the basin. Treatment liquid is pumped by means of the pump into the filling pipe and through the filling pipe openings, for example, in the direction of the bottom of the basin. This effects flows of the treatment liquid through the holes in the hole plate into the upper area of the basin to treat wafers in the wafer carrier with the treatment liquid. Here, the guiding elements concentrate the flow through the wafer carrier(s). Here, the guiding elements can be used as a guide when introducing the at least one wafer carrier into the upper area of the basin, such that the wafer carrier can be positioned at a defined position in the basin or the wafer carriers can be positioned at defined positions in the basin.

In examples, separating elements can be provided in the lower area of the basin, which are disposed between at least some of the filling pipe openings of the filling pipe and extend in a direction intersecting the longitudinal direction of the filling pipe, to at least reduce flows of the treatment liquid in the longitudinal direction of the filling pipe between the at least some of the filling pipe openings. In such examples, by providing the separating elements, a flow of the treatment liquid in the longitudinal direction of the filling pipe can be reduced, such that a more uniform flow through one or several wafer carriers disposed above the hole plate can be obtained. Thereby, a more uniform treatment of the wafers with the treatment liquid, which can also be referred to as treatment medium, can be effected. Further, this allows a more effective usage of the medium. The treatment liquid can for example, be cleaning liquids or etching liquids common for treating silicon wafers.

In examples, the separating elements can be configured to separate the lower area of the basin into partitions that extend laterally towards the outside from the filling pipe. By such a partitioning it is possible to limit the flow of the treatment liquid in longitudinal direction onto the respective partitions, wherein a circular flow can be effected in the respective partitions, by which an effective uniform flow through the hole plate disposed above can be obtained.

In examples, one separating element can be provided between each adjacent pair of filling pipe openings. This allows an extensive reduction or suppression of flows of the treatment liquid in longitudinal direction of the filling pipe.

In examples, the separating elements can extend in the direction that intersects the longitudinal direction of the filling pipe across an area of the hole plate where the holes are provided. In that way, it is possible to reduce or suppress the flow of the treatment liquid in longitudinal direction of the filling pipe across the entire area of the hole plate in which the holes are provided in transversal direction. Thereby, a uniform flow can be obtained above this entire area above which one or several wafer carriers can be disposed.

In examples, the direction in which the separating elements extend is perpendicular to the longitudinal direction of the filling pipe. Here, the direction in which the separating elements extend means the direction of the longest extension of the separating elements, wherein the separating elements can comprise a longitudinal plate shape. Therefore, examples allow, in an effective manner, a flow of the treatment liquid perpendicular to the longitudinal direction of the filling pipe in order to obtain a uniform flow of the treatment liquid above the hole plate.

In examples, the filling pipe is fluidically coupled to a treatment liquid supply line in a central area of the same in longitudinal direction, such that a uniform flow of the treatment liquid can be obtained through the filling pipe starting from the treatment liquid supply line.

### BRIEF DESCRIPTION OF THE DRAWINGS

Embodiments of the present invention will be detailed subsequently referring to the appended drawings, in which:

FIG. 1 shows a schematic cross sectional view transversal to the longitudinal direction of a filling pipe of an apparatus according to an example of the present invention;

FIG. 2 shows a schematic cross sectional view of an apparatus according to FIG. 8;

FIG. 3 shows a schematic top view of the apparatus of FIG. 1;

FIG. 4 shows a schematic cross sectional view in longitudinal direction of a filling pipe of an apparatus according to an example of the present invention;

FIG. 5 shows a schematic cross sectional view transversal to the longitudinal direction of the filling pipe of the apparatus shown in FIG. 4;

FIG. 6 shows a schematic top view of the example of the apparatus shown in FIG. 5; and

FIG. 7-10 show schematic illustrations of an apparatus that is not part of the scope of the claims, whose discussion will help the understanding of the present invention.

### DETAILED DESCRIPTION OF THE INVENTION

In the following, examples of the present invention will be described in detail and by using the accompanying drawings. It should be noted that equal elements or elements having the same functionality are provided with the same or similar reference numbers, wherein a repeated description of elements that are provided with the same or similar reference numbers is typically omitted. Descriptions of elements having the same or similar reference numbers can be inter-exchangeable. In the following description, many details will be described to provide a thorough explanation of examples of the invention. However, it is obvious for a person skilled in the art that other examples can be implemented without these specific details. Features of the differently described examples can be combined except when features of a respective combination exclude each other or such a combination is explicitly excluded.

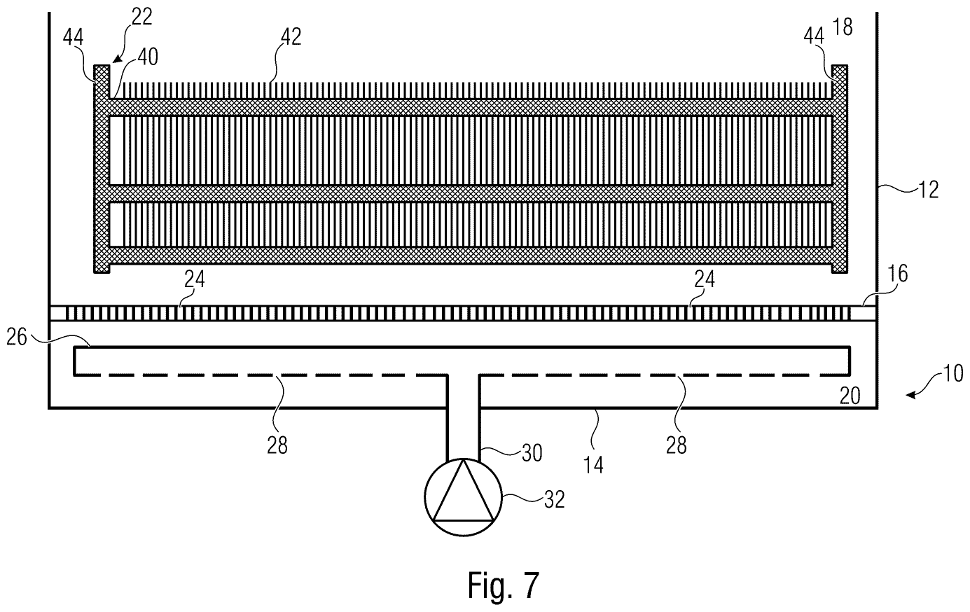

Before examples of the present invention will be discussed in more detail, first, with reference to FIGS. 7 to 10, an apparatus for treating wafers with a treatment liquid on which the invention is based will be discussed. Here, the apparatus can have a similar structure as the structure described in the above-stated TW 202003124 A.

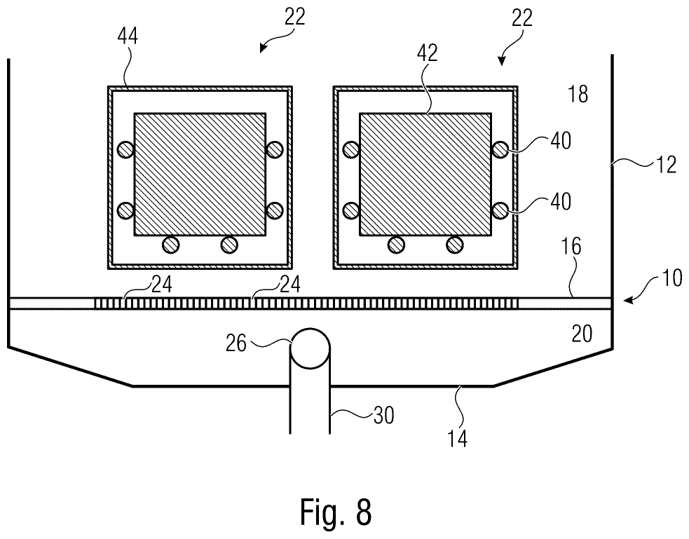

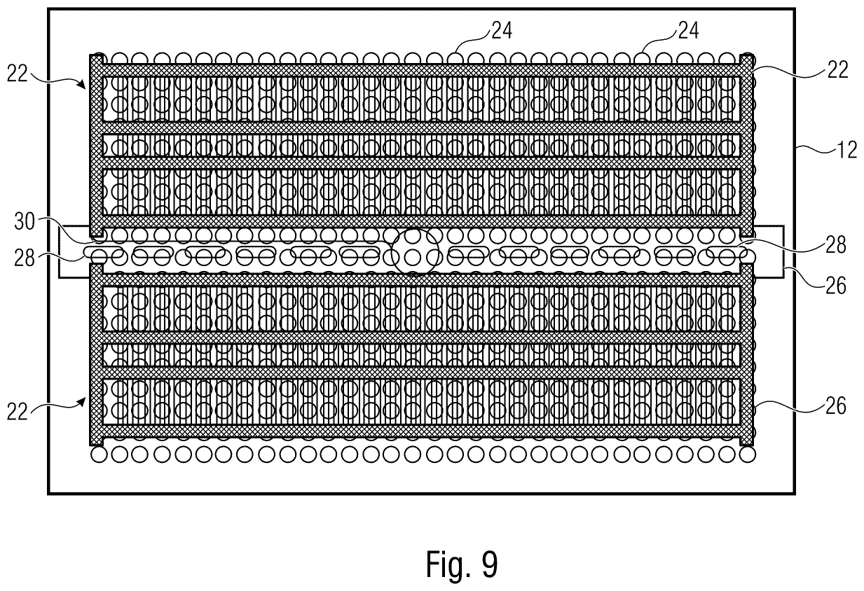

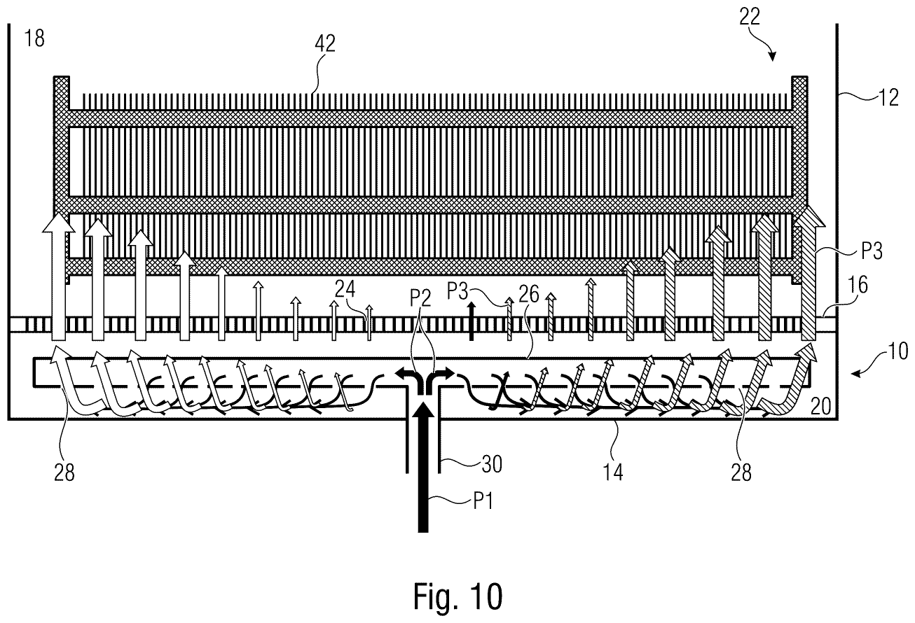

FIG. 7 shows a schematic cross-sectional view longitudinal to a longitudinal direction of a filling pipe and FIG. 8 a schematic cross-sectional view transversal to the longitudinal direction of the filling pipe. FIG. 9 shows a schematic top view of the apparatus and FIG. 10 a schematic cross-sectional view according to FIG. 7 where liquid flows are indicated by arrows.

The apparatus is configured for treating wafers in a batch processing using wafer carriers. The apparatus comprises a basin 10 for receiving a treatment liquid that can also be referred to as treatment medium. The treating liquid can be, for example, an etching medium or a cleaning medium. The basin 10 comprises sidewalls 12 that limit four sides of the basin in the shown example where the basin is square. In other examples, the basin can have a different shape, for example an oval shape or a different number of corners. Further, the basin 10 comprises a floor 14 that limits the basin towards the bottom. The basin 10 can be open towards the top. A hole plate 16 is provided in the basin 10 and separates the basin in an upper area 18 and a lower area 20. The upper area 18 is configured to allow the reception of one or several wafer carriers 22. Here, the height of the sidewalls 12 of the basin 10 is greater than the height of the wafer carrier(s) 22. While the wafer carrier 22 is shown spaced apart from the hole plate 16 in the figures, the wafer carrier 22 can also rest on the hole plate 16. In examples, holders can be provided on the hole plate 16 on which the wafer carrier 22 rests. The hole plate 16 comprises holes 24 that fluidically connect the lower area 20 of the basin 10 with the upper area 18 of the basin 10.

A filling pipe 26 is disposed in the lower area 20 of the basin 10. The filling pipe 26 comprises filling pipe openings 28 along its longitudinal direction. The filling pipe openings 28 can be oriented towards the bottom of the basin in order to allow a more uniform distribution of the treatment liquid. In other examples, the filling pipe openings can be directed obliquely towards the top, for example at any angle. In a central area in longitudinal direction of the same, the filling pipe 26 is fluidically coupled to a treatment liquid supply line 30. The treatment liquid supply line 30 is further fluidically coupled to a pump 32.

As can be best seen in FIG. 9, the holes 24 are distributed in the hole plate 16 across the area that forms one or several receiving area(s) for wafer carriers 22.

As can be seen in FIG. 9, the wafer carrier 22 has a square shape in top view. The wafer carrier 22 comprises rods 40 extending in longitudinal direction of the same, on which a plurality of wafers 42 rest side-by-side as can be seen best in FIG. 7. The rods 40 can be configured to hold the wafers 42 at a defined spacing from each other adjacent to each other. Here, as can be seen best in FIG. 8, the wafers 42 can rest on two rods 40 at the bottom and can be held on both sides by two rods 40 each. The wafer carrier 22 comprises end plates 44 on the two longitudinal ends, where the rods 40 are mounted and that hold the rods 40 in position to each other. Thus, the wafer carrier 22 comprises openings between the rods that allow a treatment liquid to flow over the wafers held therein. Respective wafer carriers are known and do not need any further discussion herein. The apparatuses described herein are suitable for treating wafers that are held by wafer carriers that allow the treatment liquid to flow over the held wafers from a bottom of the wafer carrier. For people skilled in the art, it is obvious that the wafer carrier can deviate from the wafer carrier described herein as long as the same allows a treatment liquid to flow over the held wafers. For example, the wafer carrier could comprise a different number of rods than shown herein. In other examples, the openings that allow that wafers are overflown by a treatment liquid can be formed by a grid of the wafer carrier or the same. Such wafer carriers are normally also referred to as carriers.

In the shown example, the upper area 18 of the basin comprises receiving areas for two wafer carriers 22, in such a manner that the longitudinal direction of the wafer carriers 22 is parallel to the longitudinal direction of the filling pipe 26. As can be seen in FIG. 9, the filling pipe openings 28 can be longitudinal in longitudinal direction of the filling pipe 26. In other examples, the filling pipe openings can have different shapes, for example round or longitudinal transversal to the longitudinal direction of the filling pipe. In other examples, several filling pipe openings can be provided side-by-side, each transversal to the longitudinal direction of the filling pipe.

During operation, the pump 32 pumps treatment liquid through the treatment liquid supply line 30 into the filling pipe 26, as indicated by an arrow P1 in FIG. 10. Here, the liquid is separated in two flows that flow into the respective segments of the filling pipe 26 on both sides of the treatment liquid supply line 30, as indicated by arrows P2 in FIG. 10. The liquid flowing through the filling pipe 26 leaves the filling pipe through the filling pipe openings 28 that are oriented towards the floor 14 of the basin. This results in the flows through the filling pipe openings 28 indicated in FIG. 10 by arrows. The flows are deflected at the floor 14 of the basin 10 and reach the top past the filling pipe 26. There, the treating liquid flows through the holes 24 in the hole plate and flows through the wafer carrier 22. Thereby, the wafers 42 disposed in the wafer carrier 22 are treated with the treatment liquid. If the basin is filled with treatment liquid, treatment liquid can leave the basin via the upper edge of the basin or a drain intended therefore. In examples, the treatment liquid that has left the basin can be supplied again via the treatment liquid supply line 30, via a fluid cycle, for example after recycling the same.

However, the inventors have found that a flow in the lower area 20 of the basin 10 takes place in longitudinal direction of the filling pipe, which has the consequence that the flow directed towards the top is significantly higher in edge areas of the basin 10 compared to central areas of the basin 10, as indicated by respective arrows P3 of different width in FIG. 10. However, this flow distribution has the consequence that the treatment liquid does not uniformly flow through the wafers 42 disposed in the wafer carrier 22, so that no uniform treatment of the wafers takes place.

Although in the described example the apparatus is configured for receiving two wafer carriers, in other examples, the apparatus can be configured for a different number of wafer carriers, for example an arrangement of four wafer carriers side-by-side, a 2×2 arrangement of four wafer carriers, an arrangement of 2×3 wafer carriers or also of only one wafer carrier. Although only one filling pipe is provided in the shown example, in other examples, one filling pipe could be provided for each wafer carrier, i.e. for each receiving area of a wafer carrier.

In examples, the holes 24 of the hole plate 16 are provided in a uniform two-dimensional pattern. In examples, the holes can have the same size. In examples, the holes can have different sizes.

There is no need to state that the components of the apparatus are formed of suitable materials that are resistant against the treatment liquids or treatment media by which the wafers are to be treated. In examples, the respective components can consist of suitable metal materials or plastic materials.

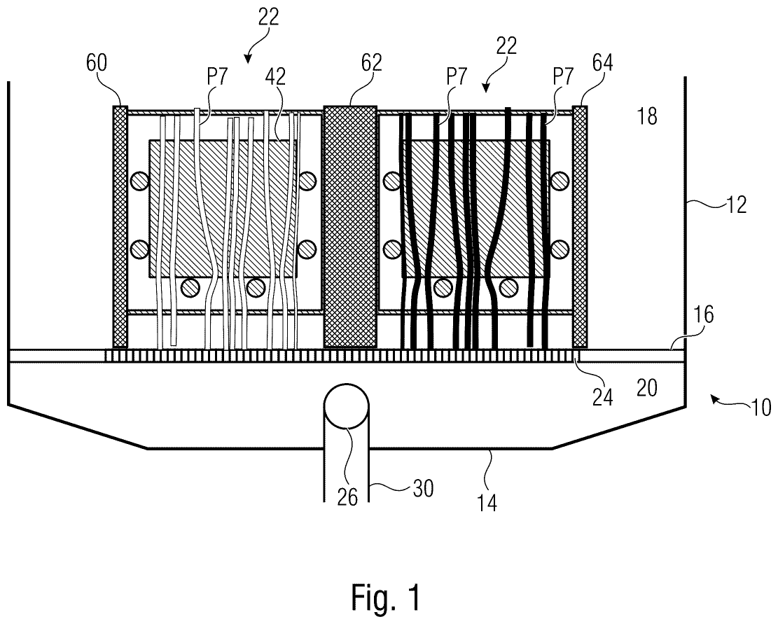

With reference to FIGS. 1 to 6, examples of the present invention will be discussed in more detail. The details stated above with reference to FIGS. 7 to 10 apply accordingly for the examples of the present invention and are not repeated again.

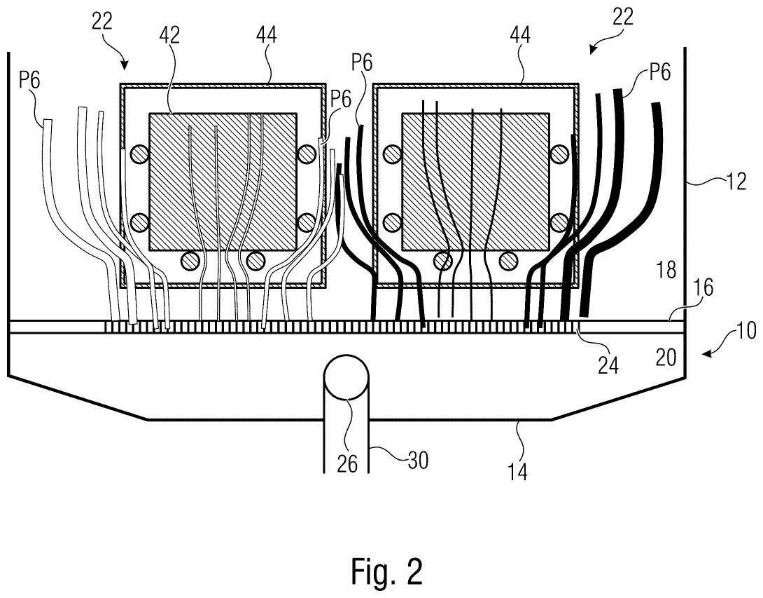

FIG. 2 shows a schematic cross-sectional view that essentially corresponds to the one of FIG. 8, wherein liquid flows in the upper area 18 of the basin 10 are illustrated by arrows P6. The liquid flow has a tendency to select the path with the lowest fluidic resistance and to flow past the wafer carriers 22, such that a large part of a liquid flows past the wafer carriers on the outside, part of the liquid flows between the two illustrated wafer carriers and only a small part of the liquid flow actually reaches between the wafers 42 through the wafer carriers 22.

To prevent this and to obtain a stronger and more homogenous flow through the wafer carriers 22 and hence the wafers 42 disposed in the wafer carriers 22, in examples of the invention, in addition to the outer walls of the basin 10, guiding elements are provided, which are disposed in the upper area 18 of the basin 10.

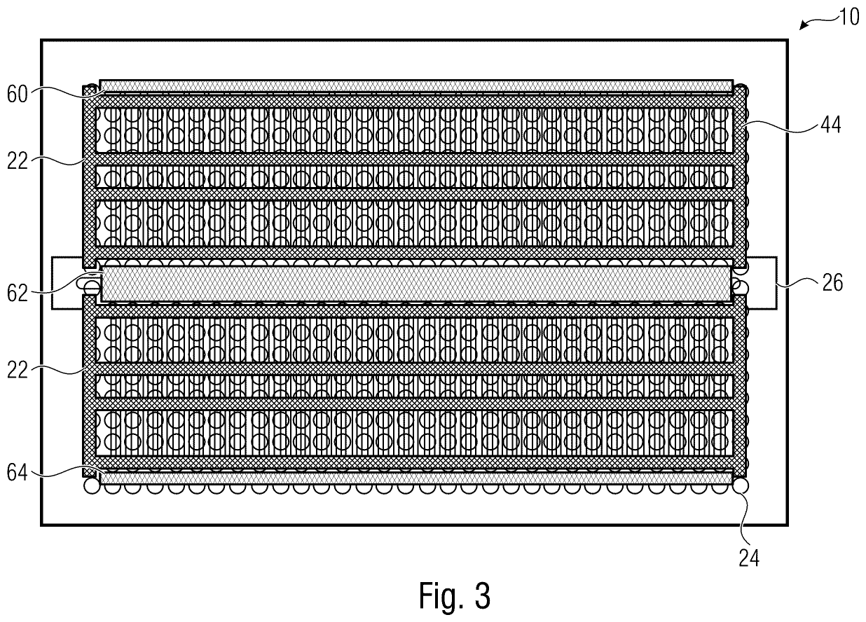

FIG. 1 shows an apparatus according to an example of the invention. As shown in FIG. 1, the apparatus comprises a basin 10 for receiving the treatment fluid and the wafers 42 to be treated, and the hole plate 26 that separates the basin 10 into an upper region 18 and a lower region 20. The hole plate comprises holes 24 that fluidically connect the lower region 20 and the upper region 18. The filling pipe 26 is arranged in the lower region 20 of the basin 10 and comprises filling pipe openings 28 along its longitudinal direction (from left to right in FIG. 3), which in the example shown are oriented towards a bottom of the basin, i.e., the floor 14. The apparatus further comprises guiding elements 60, 62, and 64. The guiding elements 60, 62, 64 are arranged in the upper area of the basin and limit the receiving area of at least one wafer carrier laterally to concentrate a flow of the treatment liquid on the receiving area. The guiding elements 60, 62 and 64 are disposed above the hole plate 16 and can be mounted on the same. The guiding element 60 limits a first receiving area for a wafer carrier at the outer edge, the guiding element 64 limits a second receiving area for a wafer carrier at an outer edge and the guiding element 62 limits the two receiving areas at the inner edge of the same.

As shown in FIG. 3, the guiding elements 60, 62 and 64 extend along the longitudinal extension of the wafer carriers 22. The guiding elements 60, 62 and 64 extend in a direction perpendicular with respect to the hole plate 16 towards the top and can serve to position the wafer carriers 22 in the upper area 18 of the basin 10. The gap between the guiding elements 60 and 62 and the gap between the guiding elements 62 and 64 can correspond to a dimension of the wafer carriers 22 in a direction perpendicular to the longitudinal direction of the filling pipe 26. More specifically, in the shown example, this gap corresponds to the width of the wafer carrier in the area of the outer holding rods 40. As can be seen in FIG. 3, in the shown example, the side plates 44 of the wafer carrier 22 project laterally beyond the rods 40. The length of the guiding elements in the longitudinal direction of the filling pipe 26 corresponds to a gap between these end plates of the wafer carrier 44. Thus, in this example, the wafer carrier can be positioned both in longitudinal direction of the filling pipe and in transversal direction of the same. In other examples, the gap between the respective guiding elements in transversal direction could also correspond to the width of the end plates 44. In examples, the side plates 44 do not project laterally across the rods 40, such that the gap between the respective guiding elements corresponds to both the width in the area of the rods and the width of the end plates.

In examples, the sides of the guiding elements facing the receiving areas are planar and extend across the entire height of the receiving areas, i.e., the wafer carriers. Thereby, it is possible to concentrate the flow across the entire height of the wafers received in the wafer carriers.

In examples, the guiding elements can have the shape of a plate, which allows for a simple structure. In examples, the guiding elements can taper in the direction in which the wafer carrier(s) are introduced to simplify introduction and positioning of the wafer carriers.

The definition that the gap between the guiding elements transversal to the longitudinal direction of the filling pipe corresponds to a dimension of the wafer carrier transversal to the longitudinal direction of the filling pipe means that this gap is slightly greater than the respective dimension to allow positioning of the wafer carrier between the guiding elements. The same applies for the definition that the length of the guiding elements in the longitudinal direction of the filling pipe corresponds to a gap between end plates of the wafer carrier, which means that the gap between the end plates of the wafer carrier is slightly greater than the length of the guiding elements in the longitudinal direction to allow that the guiding elements are positioned between the end plates.

Thus, the lateral guiding elements provide tightly limited shafts for the wafer carriers, through which the flow of the treatment medium through the hole plates onto the wafer carriers can be concentrated. Here, it should be noted that the wafers should normally not be positioned too close to the holes 24 of the hole plate 16 in order to prevent overtreatment of the wafers at locations where the same are closest to the holes. For obtaining this, the end plates 44 can project beyond the lower rods 40 towards the bottom. Alternatively, holders on which the wafer carriers are placed in the basin can be provided in the basin 10.

In FIG. 1, arrows P7 show how the liquid flow is concentrated through the wafer carriers 22 due to the guiding elements 60, 62 and 64. Thus, examples of the present invention allow a concentrated and uniform treatment of the wafers 42 that are disposed in the wafer carriers 22 with a treatment medium that flows through the holes 24 in the hole plate 16.

Although the basin 10 comprises only two receiving areas for wafer carriers 22 in the shown example, the basin can comprise a different number of receiving areas in other examples as discussed above. Respective guiding elements for the wafer carriers can be provided for each of the receiving areas. The guiding elements can be provided in the form of walls in the upper area 18 of the basin 10. The guiding elements do not have to reach up to over the upper edge of the wafer carrier 22 as shown in FIG. 1. In alternative examples, some or all of the guiding elements can have a lower height. In again alternative examples, no guiding element is provided between two wafer carriers, for example when the receiving areas of the two wafer carriers directly abut on each other or are disposed very close to each other. In examples, a guiding element disposed between two wafer carriers can have a lower height than outer guiding elements.

Thus, the guiding elements allow a specific media guidance through the wafer carriers and a homogeneous flow through the same. Thus, the treatment medium can be used more effectively, for example in etching methods or when purging the wafers. Here, apart from the concentration of the medium through the wafer carriers, the guiding elements allow the positioning of the wafer carriers in the basin, such that additional wafer carrier centering can be omitted.

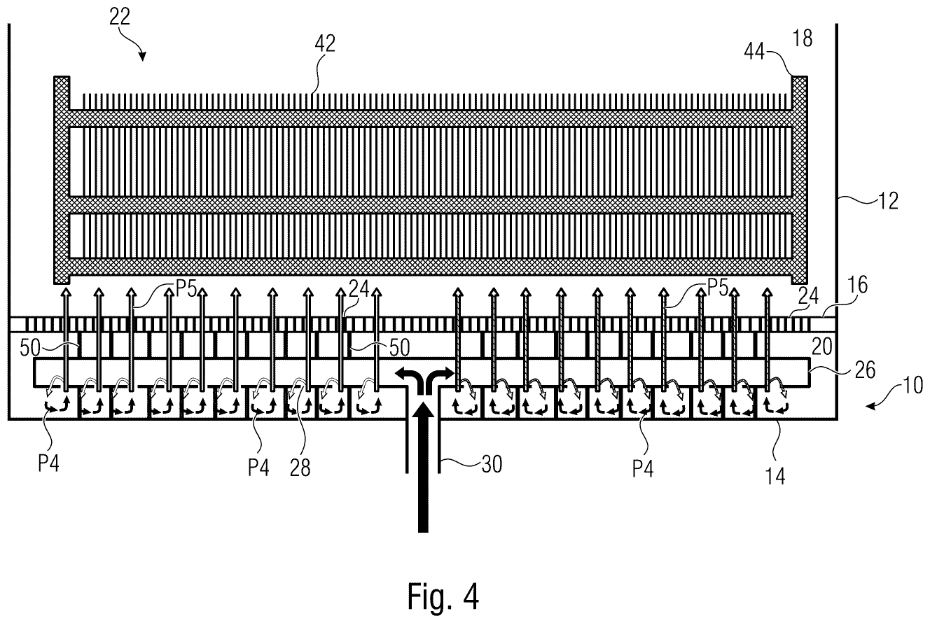

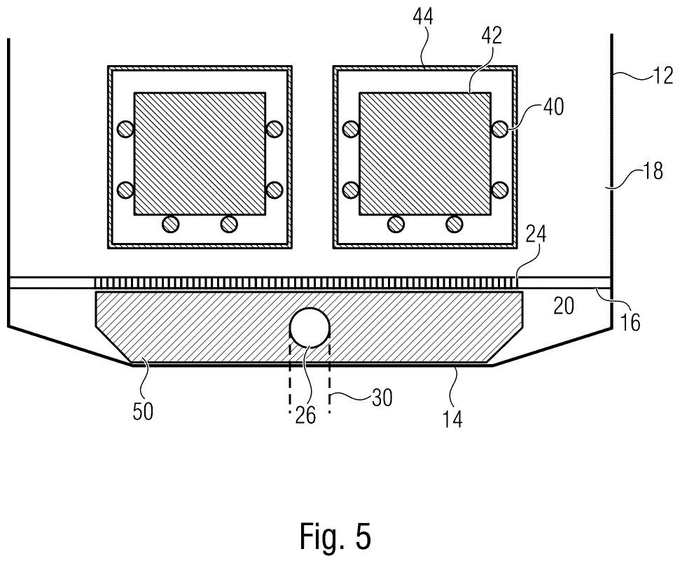

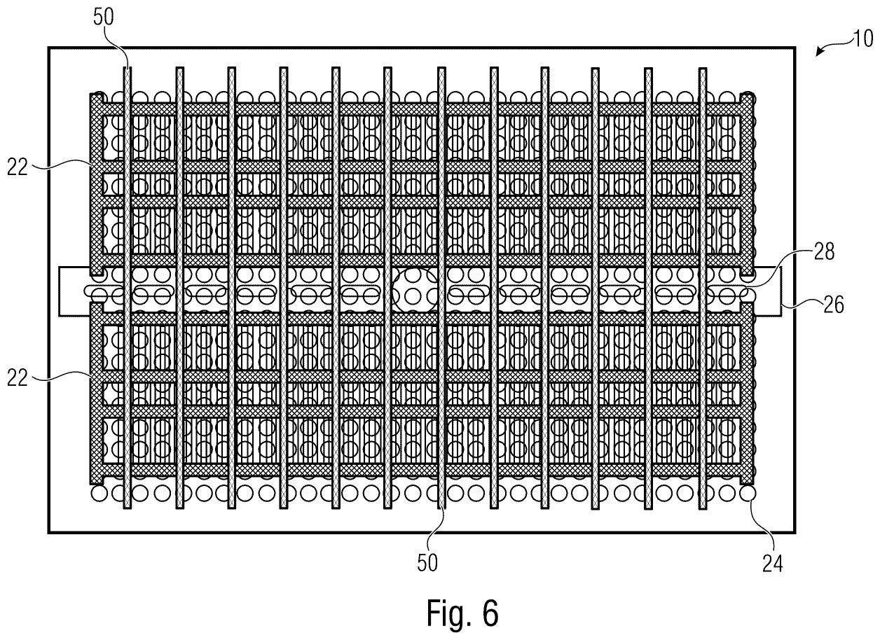

FIGS. 4 to 6 show another example of the invention, in which separating elements 50 are provided in a lower area 20 of the basin. It should be noted here that although the guiding elements are not shown in FIGS. 4 to 6, the same are additionally provided in accordance with FIGS. 1 to 3. There may also be examples corresponding to FIGS. 4 to 6 without the guiding elements, but such examples are not currently claimed. Only some of the separating elements are provided with the reference number 50. The separating elements can be located on the bottom 14 of the basin, as shown in FIG. 5, wherein in FIG. 5 a small gap between separating elements 50 and basin floor 14 is illustrated for clarifying purposes. Here, it should be noted that the number of separating elements differs in FIGS. 4 and 6, wherein this, however, is merely the case for illustration purposes. In the shown example, the separating elements extend in transversal direction (perpendicular to the longitudinal direction of the filling pipe 26) at least across the area of the hole plate 16 where the holes 24 are provided. As indicated in FIG. 6, the hole plates can extend laterally beyond this area, for example up to the sidewalls of the basin, in FIG. 6 top and bottom. In examples, the separating elements are plate-shaped. In examples, the separating elements each extend, at least in a central area, from the floor 14 of the basin 10 to the hole plate 16, as shown best in FIG. 5. In outer edge areas, the separating elements 50 can be spaced apart from the floor of the basin, in particular when the floor raises in the outer edge areas as shown in FIG. 5.

The separating elements 50 extend in a direction perpendicular to the longitudinal direction of the filling pipe 26. In other examples, the separating elements could also extend at a slight angle to this direction, for example at an angle ≤10°.

In examples, one separating element 50 is provided between each adjacent pair of filling pipe openings. In other examples, a smaller number of separating elements could be provided, wherein, for example two filling pipe openings could be provided each between two separating elements. In other examples, the separating elements could be provided in an irregular manner, wherein the gap between separating elements could be greater in the central area and could be lower in an outer area.

The separating elements 50 disposed below the hole plate 16, i.e. below the wafer carrier plane separate the lower area 20 into partitions that segment the flow from the filling pipe. In examples, the partitions have a shape running perpendicular to the longitudinal direction of the filling pipe 26. A respective segmentation of the flow cannot be obtained by a simple filling pipe.

In examples, the separating elements can reach down to the floor of the basin, up to the hole plate and laterally at least to the end of the area where the holes are disposed in a hole plate. Thereby, in this area, flows in longitudinal direction of the filling pipe past the separating elements can be completely prevented. In other examples, the upper and lower ends of the separating elements can have a gap from the hole plate or the floor of the basin. In examples, the separating elements can be attached to the filling pipe. In examples, the separating elements can be attached to the hole plate and can comprise a recess below the filling pipe that allows pushing the separating elements over the filling pipe from above. In examples, the separating elements can be attached to the floor and can comprise a recess above the filling pipe, such that the filling pipe can be introduced from above. Such a configuration of the separating elements with a recess can simplify an assembly without significantly influencing the functionality.

In examples, the filling pipe openings 28 can be longitudinal in the longitudinal direction of the filling pipe. In examples, the filling pipe openings 28 can comprise an extension in the longitudinal direction of the filling pipe that essentially corresponds to the gap between two separating elements 50, whereby a more homogenous distribution into the respective partition is possible.

The separating walls reduce flows of the treatment liquid in longitudinal direction of the filling pipe 26 between the filling pipe openings 28, between which the separating walls 50 are disposed. This generates, as shown in FIG. 4, a circular flow P4 in the respective partitions. This circular flow P4 results in a more uniform liquid flow through the openings 24 of the hole plate 16 as indicated by arrows P5 in FIG. 4.

Thus, the separating elements configured in the shape of lands generate segmentation along the filling pipe, by which the differences of the flows through the holes 24 of the hole plate 16 in longitudinal direction of the filling pipe 26 can be reduced. Thereby, the treatment liquid flows through the wafer carrier(s) 22 disposed in the upper area 18 of the basin 10 in a more uniform manner. Thus, a more uniform treatment of the wafers 42 disposed in the wafer carriers 22 can be obtained, wherein the liquid flows through the same from bottom to top.

Apart from homogenization of the flow through the holes 24 of the hole plate, the separating elements 50 can further have a supporting effect for the hole plate 16 and the filling pipe 26, such that the stability of the basin and hence the basin statics can be improved.

In respective methods for treating wafers, the pump 32 (shown in FIG. 7) fluidically coupled to the treatment liquid supply line 30 pumps treatment liquid into the filling pipe 26 and through the treatment pipe openings 28 in the direction of the bottom of the basin, wherein flows of the treatment liquid through the holes 24 in the hole plate 16 into the upper area 18 of the basin are effected. The guiding elements obtain a concentration of the flows through the wafer carriers and a further homogenization of the flow through the same. Further, in examples, these flows can be homogenized due to the partitions formed by the separating elements 50, compared to strongly inhomogeneous flows as they would take place without the separating elements, see the flows P3 in FIG. 10. By these flows, wafers 42 can be treated uniformly with the treatment liquid in a wafer carrier 22 that has been previously introduced into the upper area 18 of the basin 10.

Examples of the present invention can specifically relate to the treatment of semiconductor wafers in baskets in a batch processing, wherein the treatment can consist, for example, in etching the wafer surfaces or cleaning of the wafer surfaces. Respective treatment liquids for semiconductor wafers, for example silicon wafers, are known to a person skilled in the art and do not require any further discussion herein.

Although features of the invention have been described in connection with a features of a device or features of a method, it is understood for a person skilled in the art that respective features can also to be part of a method or a device. The device can thus be configured to perform corresponding method steps, and the respective functionality of the device can represent corresponding method steps.

In the preceding detailed description, various features were sometimes grouped together in examples in order to rationalize the disclosure. This type of disclosure is not intended to be interpreted as an intention that the claimed examples have more features than are expressly stated in each claim. Rather, as the following claims disclose, the object may lie in less than all of the features of a single disclosed example. Consequently, the following claims are hereby incorporated into the detailed description, wherein each claim may stand as its own separate example. While each claim may stand as its own separate example, it should be noted that although dependent claims in the claims refer back to a specific combination with one or more other claims, other examples also include a combination of dependent claims with the object of any other dependent claim or a combination of any feature with other dependent or independent claims. Such combinations are included unless it is stated that a specific combination is not intended. It is further intended that a combination of features of a claim with any other independent claim is also encompassed, even if that claim is not directly dependent on the independent claim.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. An apparatus for treating wafers with a treatment liquid, comprising:
a basin for receiving the treatment liquid and the wafers to be treated;
a hole plate separating the basin in an upper area and a lower area, wherein the hole plate comprises holes that fluidically connect the lower area and the upper area, wherein the upper area comprises a receiving area for one or several wafer carriers in which wafers are each disposed side-by-side with a gap in between; and
a filling pipe disposed in the lower area of the basin and comprising filling pipe openings along its longitudinal direction;
further comprising guiding elements that are disposed in the upper area of the basin, in addition to outer walls of the basin, and laterally limit the receiving area of at least one wafer carrier to concentrate a flow of the treatment liquid on the receiving area,
wherein the guiding elements extend from the hole plate to a height corresponding at least to the height of the at least one wafer carrier.

2. The apparatus according to claim 1, wherein the guiding elements limit the receiving area of the at least one wafer carrier on two sides that extend in parallel to the longitudinal extension of the filling pipe.

3. The apparatus according to claim 1, wherein the guiding elements are configured to position the at least one wafer carrier in the basin.

4. The apparatus according to claim 1, wherein a gap between the guiding elements transversal to the longitudinal direction of the filling pipe corresponds to a dimension of the wafer carrier transversal to the longitudinal direction of the filling pipe.

5. The apparatus according to claim 1, wherein a length of the guiding elements in the longitudinal direction of the filling pipe corresponds to a gap between end plates of the wafer carrier.

6. The apparatus according to claim 1 comprising a plurality of respective guiding elements in the upper area of the basin, which laterally limit the receiving areas for a plurality of wafer carriers.

7. The apparatus according to claim 6, wherein the guiding elements comprise at least one guiding element that limits sides of two adjacent receiving areas that are facing each other.

8. The apparatus according to claim 1, wherein the holes in the hole plate are distributed at least across the receiving area(s).

9. The apparatus according to claim 1 comprising a pump for pumping the treatment liquid into the filling pipe and through the filling pipe openings.

10. A method for treating wafers with a treatment liquid using an apparatus according to claim 9, comprising:
introducing at least one wafer carrier into the upper area of the basin by using the guiding elements as guide; and
pumping the treatment liquid by means of the pump into the filling pipe and through the filling pipe openings to thereby bring liquid through the holes in the hole plate into the upper area of the basin to treat wafers in the wafer carrier with the treatment liquid.
